(19) United States
(12) Patent Application Publication
(10) Pub. No.: US 2025/0138231 A1
(43) Pub. Date: May 1, 2025

(54) Optical Films for Display Systems

(71) Applicant: 3M INNOVATIVE PROPERTIES COMPANY, St. Paul, MN (US)

(72) Inventors: Matthew B. Johnson, Woodbury, MN (US); Bharat R. Acharya, Woodbury, MN (US)

(21) Appl. No.: 18/836,889

(22) PCT Filed: Jan. 31, 2023
(86) PCT No.: PCT/IB2023/050840

§ 371 Date: Aug. 8, 2024

Related U.S. Application Data
(60) Provisional application No. 63/312,592, filed on Feb. 22, 2022.

(51) Int. Cl. G02B 5/28

(52) U.S. Cl. CPC G02B 5/28

(57) ABSTRACT

A display system includes a light source emitting blue light including blue wavelength, and UV light including UV wavelength. A first multilayer optical film (MOF) is disposed between a display panel and a second MOF. Light conversion films receive and convert emitted blue light to green and red lights. At incident angles of less than 10 degrees, the first MOF transmits greater than 50% of light for the blue wavelength and reflects greater than 60% for green and red peak wavelengths. The second MOF transmits greater than 50% for blue, green and red peak wavelengths, and reflects greater than about 60% for the UV wavelength. At oblique incident angles, the first MOF reflects greater than 50% for the blue, green and red peak wavelengths, and the second MOF transmits greater than 50% for the blue, green and red peak wavelengths, and transmits greater than 60% for the UV wavelength.

### TECHNICAL FIELD

The present disclosure generally relates to optical films, specifically to multilayer optical film constructions for backlighting display systems.

### BACKGROUND

Display systems, such as liquid crystal display (LCD) systems, are used in a variety of applications and commercially available devices such as, for example, computer monitors, personal digital assistants (PDAs), mobile phones, miniature music players, and thin LCD televisions. Many LCDs include a liquid crystal panel and an extended area light source, often referred to as a backlight, for illuminating the liquid crystal panel. Backlights typically include one or more light sources and a number of light management films such as, for example, light guides, mirror films, light redirecting films (including brightness enhancement films), retarder films, light polarizing films, and diffusing films. Other materials can be included in one or more of the layers of the light management films to reduce the adverse effects of UV light.

### SUMMARY

In some aspects of the present disclosure, an optical stack including one or more light converting layers is provided. The one or more light converting layers includes a green emission spectrum having at least one green peak at a corresponding green peak wavelength and a red emission spectrum having at least one red peak at a corresponding red peak wavelength. The one or more light converting layers are configured to receive a blue light including a blue wavelength spectrum having at least one blue peak at a corresponding blue peak wavelength and convert portions of the received blue light to green and red lights within the respective green and red emission spectra. A first optical film is disposed on, and is substantially co-extensive in length and width with, the one or more light converting layers. The first optical film includes a plurality of first layers numbering at least 4 in total. Each of the first layers has an average thickness of less than about 500 nm. For an incident light incident at an incident angle of less than about 10 degrees, the first optical film transmits greater than about 50% of the incident light for the blue wavelength and reflects greater than about 60% of the incident light for each of the green and red peak wavelengths. For an incident light incident at an incident angle of greater than about 40 degrees, the first optical film reflects greater than about 50% of the incident light for each of the blue, green and red peak wavelengths.

In some other aspects of the present disclosure, a display system is provided. The display system includes at least one light source configured to emit a blue light including a blue wavelength spectrum having at least one blue peak at a corresponding blue peak wavelength, and emit an ultraviolet (uv) light having a uv wavelength less than the blue peak wavelength. A display panel is disposed to receive light from the at least one light source and form an image. A first optical film is disposed between the display panel and a second optical film. The display system includes one or more light converting layers including a green emission spectrum having at least one green peak at a corresponding green peak wavelength and a red emission spectrum having at least one red peak at a corresponding red peak wavelength. The one or more light converting layers are configured to receive the emitted blue light and convert portions of the received blue light to green and red lights within the respective green and red emission spectra. For an incident light incident at an incident angle of less than about 10 degrees, the first optical film transmits greater than about 50% of the incident light for the blue wavelength and reflects greater than about 60% of the incident light for each of the green and red peak wavelengths and the second optical film transmits greater than about 50% of the incident light for each of the blue, green and red peak wavelengths, and reflects greater than about 60% of the incident light for the uv wavelength. For an incident light incident at an incident angle of greater than about 40 degrees, the first optical film reflects greater than about 50% of the incident light for each of the blue, green and red peak wavelengths, and the second optical film transmits greater than about 50% of the incident light for each of the blue, green and red peak wavelengths, and transmits greater than about 60% of the incident light for the uv wavelength.

In some aspects of the present disclosure, a display system including a display panel disposed on an optical stack of one or more embodiments of the disclosure and configured to form an image is provided.

These and other aspects will be apparent from the following detailed description. In no event, however, should this brief summary be construed to limit the claimable subject matter.

### BRIEF DESCRIPTION OF THE DRAWINGS

FIG. 1 is a schematic cross-sectional view of a display system including various light management films;

FIG. 2 illustrates the emission spectrum of the blue light emitted by the light emitting sources, the emission spectra of the light conversion film, and the transmittance versus wavelength of optical films at different incident angles according to some embodiments;

FIG. 3 is a schematic cross-sectional view of a multilayer optical construction of the optical films in the optical stack according to some embodiments; and

FIG. 4 is a schematic cross-sectional view of an optical stack according to some embodiments.

### DETAILED DESCRIPTION

In the following description, reference is made to the accompanying drawings that form a part hereof and in which various embodiments are shown by way of illustration. The drawings are not necessarily to scale. It is to be understood that other embodiments are contemplated and may be made without departing from the scope or spirit of the present description. The following detailed description, therefore, is not to be taken in a limiting sense.

There has been an explosive growth in the number and variety of display devices in recent times. Computers (whether desktop, laptop, or notebook), personal digital assistants (PDAs), mobile phones, and thin LCD TVs are but a few examples. Although some of these devices can use ordinary ambient light to view the display, most include a light panel referred to as a backlight to make the display visible. In many applications, Liquid Crystal Displays (LCDs) require a backlight unit as an illuminator that is efficient and uniform spatially, angularly, and spectrally.

Many such backlights fall into the categories of “edge-lit” or “direct-lit”. These categories differ in the placement of the light sources relative to the output area of the backlight, where the output area defines the viewable area of the display device. In edge-lit backlights (1-D), a light source is disposed along an outer border of the backlight construction, outside the zone corresponding to the output area. The light source typically emits light into a light guide, which has length and width dimensions on the order of the output area and from which light is extracted to illuminate the output area. In direct-lit backlights, an array (2-D) of light sources is disposed directly behind the output area, and a diffuser is placed in front of the light sources to provide a more uniform light output. Backlights generally require optical films above the light source to achieve the uniformity and brightness specifications. Some direct-lit backlights also incorporate an edge-mounted light, and are thus capable of both direct-lit and edge-lit operation. The direct-lit backlighting technique is an effective means to provide a wide range of brightness for independent regions of the display, referred to as High Dynamic Range (HDR), improving the user visual experience.

The present disclosure describes direct-lit backlight units having optical stack configurations with UV reflective properties for the purpose of reducing eye strain and increasing lifetime performance of the other optical film layers within the optical stack.

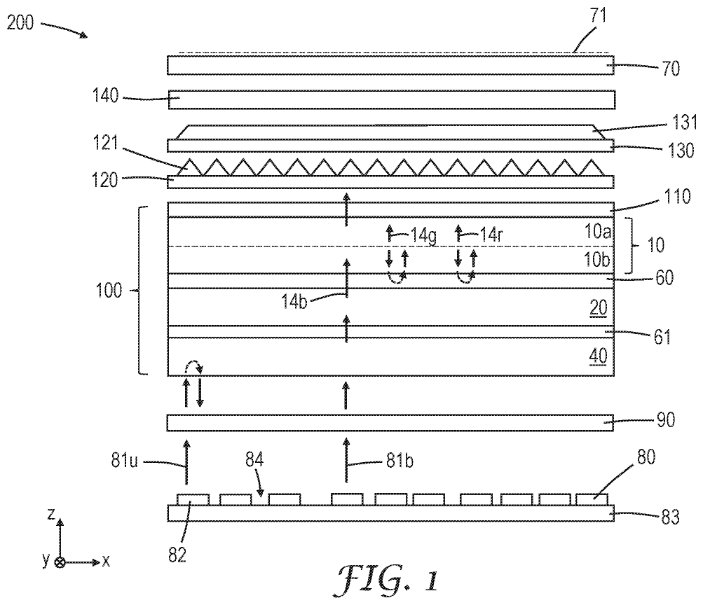

FIG. 1 is a schematic cross-sectional view of an illustrative display system (200) according to some embodiments. The display system (200) includes a display panel (70) illuminated from behind by a backlight system. The display system (200) is shown in the context of a Cartesian x-y-z coordinate system, where the z-axis substantially corresponds to surface normal to the display panel (70) and the backlight. The display panel (70), in some aspects, may include a liquid crystal display (LCD) panel. The LCD panel may have a multitude of electronically addressable picture elements (pixels) to enable electronically addressable images. However, in some embodiments the display panel (70) may be of a simpler design and may not include an LCD panel. For example, the display panel may be or include a light-transmissive film or other substrate on which is printed a static image.

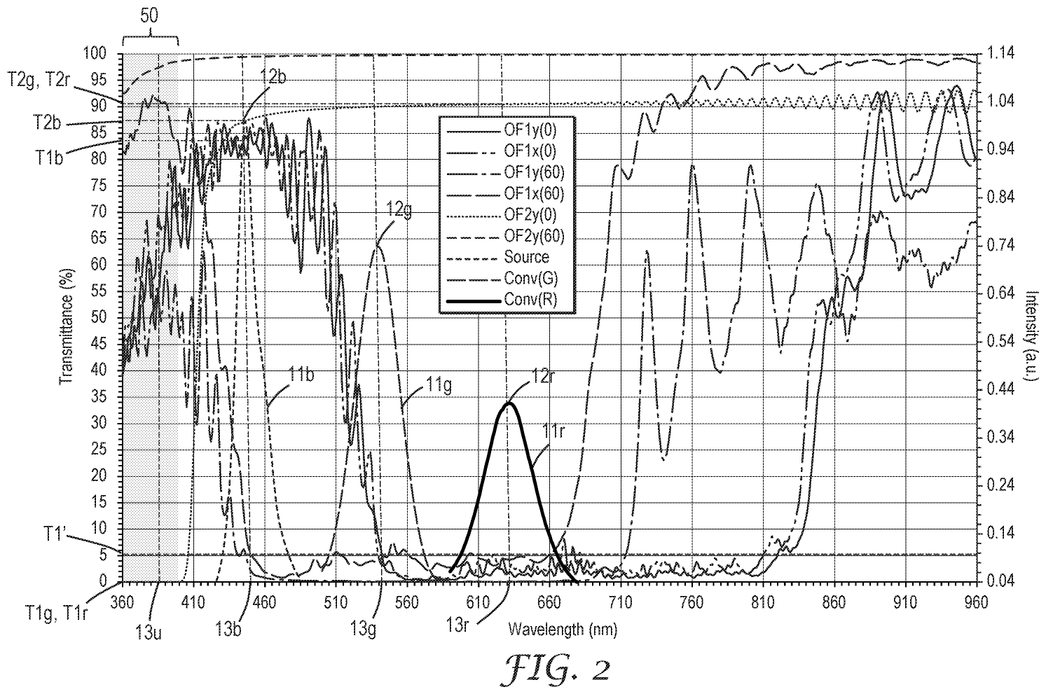

The backlight system includes at least one light source (80) configured to emit a blue light (81b) and an ultraviolet (UV) light (81u). The display panel (70) can be disposed to receive light from the at least one light source (80) to form an image (71). In some aspects, the backlight system may include a plurality of light emitting sources (80) configured to emit a blue light (81b) and UV light (81u). The emitted blue light (81b) may have a blue wavelength spectrum (11b) including at least one blue peak (12b) at a corresponding blue peak wavelength (13b) as shown in FIG. 2. The UV light (81u) may have a UV wavelength (13u) in the UV wavelength range (50) as shown in FIG. 2. The UV wavelength (13u) may be less than the blue peak wavelength (13b). The plurality of light emitting sources (80) may include a 2-D array of discrete spaced apart light emitting sources formed by placing the light emitting sources (80) in a square pattern or in any regular pattern as desired. In some aspects, a number of light emitting sources are arranged to form a zone and zones are arranged in a regular pattern. The actual number of light emitting sources (80) needed depends on the size of the display panel (70), the luminous flux of each light emitting source (80), and the desired brightness. In some aspects, the one or more light emitting sources (80) may include a plurality of discrete light emitting diodes (LEDs). The LEDs that form the 2-D array of discrete light emitting sources are in electrical communication such that the LEDs can operate in a series or parallel manner or a combination of series and parallel as desired.

In some aspects, the one or more discrete spaced apart light emitting sources (80) may be disposed on a common substrate (83). In some aspects, the common substrate (83) may be a circuit board having a plurality of electrically conductive traces connected to the light emitting sources (80) for energizing and controlling a light emission of the light emitting sources (80). In regions (84) between the one or more light emitting sources (80), the common substrate (83) may have an optical reflectance of greater than about 50%, or greater than about 55%, or greater than about 60%, or greater than about 65%, or greater than about 70%, or greater than about 75%, or greater than about 80%, or greater than about 85%, or greater than about 90%, or greater than about 95% for at least an emitted wavelength.

In some embodiments, the display system (200) is disposed on an optical stack (100). The optical stack (100) according to one or more aspects disclosed herein include one or more multilayer optical films (MOF) including areas of substantially blue transmission for light substantially perpendicular to the film plane while also being substantially red and green reflecting for the other regions of the visible spectra. The MOF also includes the ability to reflect UV or lower blue wavelength ranges, which can be emitted by the light emitting sources (80), such as blue LED elements.

The construction of the optical stack (100) will be explained further with reference to FIGS. 1-4. The optical stack (100) may include one or more light conversion regions (10) configured to receive the light from the one or more light emitting sources (80). The one or more light conversion regions (10) may include one or more light converting layers (10a, 10b). The light emitted by the light emitting sources (80) has a shorter wavelength than the wavelength emitted from the light converting layers (10a, 10b). The light converting layers (10a, 10b) may be configured to provide uniform distribution and luminance uniformity of emitted light than the light emitted by the light emitting sources (80) including the LEDs.

In some aspects, light converting layers (10a, 10b) may include one or more light converting materials usually configured to receive light having a first wavelength and, in response, emit a second light having one or more different second wavelengths. In some cases, the first wavelength may be smaller than the one or more different second wavelengths. For instance, the first wavelength may be less than about 420 nm and the one or more different second wavelengths may be greater than about 420 nm. For example, light emitting sources (80) including LEDs usually emit blue light, and the light converting layers (10a, 10b) may be configured to convert a portion of the blue light into red and green components. The one or more light converting materials can include one or more of photoluminescent substances, fluorescent substances or dyes, phosphors such as blue/green/red phosphors, quantum dots, semiconductor-based optical converters, or the like in a matrix of polymers such as epoxides, acrylics, urethanes, SEBS, etc. Light-converting materials also can include rare earth elements.

According to some aspects as shown in FIG. 2, the one or more light converting layers (10a, 10b) may include a green emission spectrum (11g) including at least one green peak (12g) at a corresponding green peak wavelength (13g) and a red emission spectrum (11r) including at least one red peak (12r) at a corresponding red peak wavelength (13r). The one or more light converting layers (10a, 10b) is configured to receive a blue light (14b) and convert at least portions of the received blue light (14b) to green (14g) and red (14r) lights within the respective green (11g) and red (11r) emission spectra. In some instances, the one or more light converting layers may include at least first (10a) and second (10b) light converting layers including the respective green and red emission spectra. The first (10a) and second (10b) light converting layers may be configured to receive the blue light and convert at least portions of the received blue light (14b) to the green (14g) and red (14r) lights within the respective green (11g) and red (11r) emission spectra.

The optical stack (100) includes a first optical film (20) disposed on the one or more light converting layers (10a, 10b). In some aspects, the first optical film (20) may be substantially co-extensive in a length (y-axis) and a width (x-axis) with the one or more light converting layers (10a, 10b).

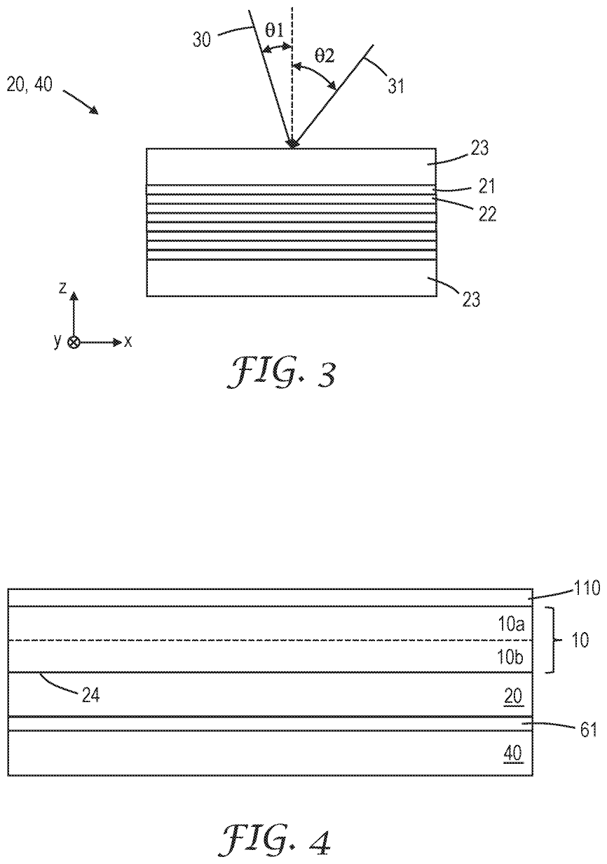

The first optical film (20) may be configured as a multilayer optical film including a plurality of first layers (21, 22), as shown in FIG. 3. The plurality of first layers (21, 22) may include a plurality of polymeric layers. The plurality of first layers (21, 22) may reflect or transmit light primarily by constructive or destructive optical interference. For instance, the plurality of first layers (21, 22) may have different refractive index characteristics so that some light is reflected at interfaces between adjacent layers. The plurality of first layers (21, 22) may be sufficiently thin so that light reflected at a plurality of interfaces undergoes constructive or destructive interference to give the first optical film (20) the desired reflective or transmissive properties.

In some cases, the plurality of first layers (21, 22) may include a plurality of alternating first polymeric A (21) and first polymeric B (22) layers. The first polymeric A layers (21) may be substantially isotropic, i.e., refractive indices along two orthogonal in-plane directions are similar (nx˜ny) and the first polymeric B layers (22) may be substantially birefringent i.e., nx≠ny. For example, the first polymeric A and first polymeric B layers (21, 22) may be designed using alternating layers of birefringent PEN and isotropic PMMA. Other combinations of high and low index materials may be used, such as alternating PET and PMMA layers.

In some other cases, the plurality of first layers (21, 22) may include a plurality of vapor deposited alternating first organic (21) and first inorganic (22) layers. For instance, the first organic layers (21) may include a polymer. For example, the polymeric first layers (21) may include one or more of a polycarbonate (PC), a polymethyl methacrylate (PMMA), a polyethylene terephthalate (PET), CoPMMA with PET, a glycol-modified polyethylene terephthalate (PETG), a polyethylene naphthalate (PEN), PC:PETG alloy, and a PEN/PET copolymer.

The first inorganic layers (22) may include one or more of an oxide, a nitride, a carbide, and a metal. The oxide may include a metal oxide, silicon oxide, silicon dioxide, zirconium oxide and titanium oxide or combinations thereof. The metal oxide may include, for example, oxides of indium, tin or alloys of indium tin. The nitride may include, for example, silicon nitride, zirconium nitride and titanium nitride or combinations thereof. The carbide may include, for example, one or more of silicon carbide and germanium carbide or combinations thereof. In some instances, the metal may include, for example, one or more of gold, silver and aluminum or alloys thereof.

The number of the plurality of first layers (21, 22) may be at least 4, or at least 6, or at least 8, or at least 10, or at least 20, or at least 30, or at least 50, or at least 75, or at least 100, or at least 150, or at least 200 in total. Each of the first layers (21, 22) may have an average thickness of less than about 500 nm. In some instances, the average thickness may be less than about 400 nm, or less than about 350 nm, or less than about 300 nm, or less than about 250 nm, or less than about 200 nm. In some aspects, the first optical film (20) may further include at least one skin layer (23) having an average thickness of greater than about 500 nm, or greater than about 750 nm, or greater than about 1000 nm, or greater than about 1500 nm, or greater than about 2000 nm.

In some aspects, a first optical bonding layer (60) may bond the one or more light converting layers (10a, 10b) to the first optical film (20). The bonding layer (60) may be an optically clear adhesive. In some other aspects, as best shown in FIG. 4, the one or more light converting layers (10a, 10b) may be coated on a major surface (24) of the first optical film (20).

The first optical film (20) may be configured to transmit incident light for the blue wavelength and reflect incident light for each of the green and red peak wavelengths. In some embodiments, for an incident light (30) incident at an incident angle (θ1) of less than about 10 degrees, or less than about 8 degrees, or less than about 6 degrees, or less than about 4 degrees, or less than about 3 degrees, or less than about 2 degrees, or less than about 1 degree, the first optical film (20) may be said to be substantially transmissive if more than about 50% of the incident light (30) for the blue wavelength is transmitted (T1b) by the first optical film (20). In some other embodiments, more than 55%, or 60%, or 65%, or 70%, or 75%, or 80% of the incident light (30) for the blue wavelength incident at an incident angle (θ1) of less than about 10 degrees may be transmitted (T1b) by the first optical film (20).

In some embodiments, for an incident light (30) incident at an incident angle (θ1) of less than about 10 degrees, or less than about 8 degrees, or less than about 6 degrees, or less than about 4 degrees, or less than about 3 degrees, or less than about 2 degrees, or less than about 1 degree, the first optical film (20) may be said to be substantially reflective if more than about 60% of the incident light (30) for each of the green and red peak wavelengths is reflected (1-T1g, 1-T1r) by the first optical film (20). In some other embodiments, more than about 65%, or 70%, or 80%, or 85%, or 90%, or 95%, or greater than about 99% of the incident light (30) for each of the green and red peak wavelengths incident at an incident angle (θ1) of less than about 10 degrees may be reflected (1-T1g, 1-T1r) by the first optical film (20).

In some embodiments, for an incident light (31) incident at an incident angle (θ2) of greater than about 40 degrees, or greater than about 45 degrees, or greater than about 50 degrees, or greater than about 55 degrees, the first optical film (20) may be said to be substantially reflective if more than 50% of the incident light for each of the blue, green and red peak wavelengths is reflected (1-T1′) by the first optical film (20). In some other embodiments, more than 55%, or 60%, or 65%, or 70%, or 75%, or 80%, or 85%, or 90%, or greater than 95% of the incident light (31) for each of the blue, green and red peak wavelengths incident at an incident angle (θ2) of greater than about 40 degrees may be reflected (1-T1′) by the first optical film (20).

In one embodiments, the optical stack (100) may further include a second optical film (40) disposed on the one or more light converting layers (10a, 10b) and the first optical film (20). In some aspects, the second optical film (40) may be substantially co-extensive in length and width with, the one or more light converting layers (10a, 10b) and the first optical film (20). In the illustrated embodiment shown in FIG. 1, the first optical film (20) is disposed between the second optical film (40) and the one or more light converting layers (10a, 10b). In other aspects, the first optical film (20) may be disposed between the display panel (70) and the second optical film (40).

In some aspects, a second optical bonding layer (61) may be provided to bond the second optical film (40) to the first optical film (20). The bonding layer (61) may be an optically clear adhesive.

The second optical film (40) may also be configured as a UV cut multilayer optical film including a plurality of second layers (21, 22), as shown in FIG. 3. The plurality of second layers (21, 22) may include a plurality of polymeric layers. The plurality of second layers (21, 22) may reflect or transmit light primarily by constructive or destructive optical interference. For instance, the plurality of second layers (21, 22) may have different refractive index characteristics so that some light is reflected at interfaces between adjacent layers. The plurality of second layers (21, 22) may be sufficiently thin so that light reflected at a plurality of interfaces undergoes constructive or destructive interference to give the second optical film (40) the desired reflective or transmissive properties.

In some cases, the plurality of second layers (21, 22) may include a plurality of alternating second polymeric A (21) and second polymeric B (22) layers. The second polymeric A layers (21) may be substantially isotropic, i.e., refractive indices along two orthogonal in-plane directions are similar (nx˜ny) and the second polymeric B layers (22) may be substantially birefringent i.e., nx≠ny. For example, the second polymeric A and second polymeric B layers (21, 22) may be designed using alternating layers of birefringent PEN and isotropic PMMA. Other combinations of high and low index materials may be used, such as alternating PET and PMMA layers or PET and a copolymer of PMMA or PC:CoPET alloy

In some other cases, the plurality of second layers (21, 22) may include a plurality of vapor deposited alternating second organic (21) and second inorganic (22) layers. For instance, the second organic layers (21) may include a polymer, and in some cases a crosslinked polymer. For example, the polymeric second layers (21) may include one or more of a polycarbonate, a polymethyl methacrylate (PMMA), an acrylic based polymer or copolymer, a polyethylene terephthalate (PET), a glycol-modified polyethylene terephthalate (PETG), a copolymer of PET that is substantially amorphous, a polyethylene naphthalate (PEN), PC:CoPET alloy, and a PEN/PET copolymer.

The second inorganic layers (22) may include one or more of an oxide, a nitride, a carbide, and a metal. The oxide may include a metal oxide, silicon oxide, silicon dioxide, zirconium oxide and titanium oxide or combinations thereof. The metal oxide may include, for example, oxides of indium, tin or alloys of indium tin. The nitride may include, for example, silicon nitride, zirconium nitride and titanium nitride or combinations thereof. The carbide may include, for example, one or more of silicon carbide and germanium carbide or combinations thereof. In some instances, the metal may include, for example, one or more of gold, silver and aluminum or alloys thereof.

The number of the plurality of second layers (21, 22) may be at least 4, or at least 6, or at least 8, or at least 10, or at least 20, or at least 30, or at least 50, or at least 75, or at least 100, or at least 150, or at least 200 in total. Each of the second layers (21, 22) may have an average thickness of less than about 500 nm. In some instances, the average thickness may be less than about 400 nm, or less than about 350 nm, or less than about 300 nm, or less than about 250 nm, or less than about 200 nm. In some aspects, the second optical film (40) may further include at least one skin layer (23) having an average thickness of greater than about 500 nm, or greater than about 750 nm, or greater than about 1000 nm, or greater than about 1500 nm, or greater than about 2000 nm.

At an incident angle (θ1) of less than about 10 degrees, the second optical film (40) may be configured to substantially transmit incident light (30) for each of the blue (12b), green (12g) and red (12r) peak wavelengths.

As shown in FIGS. 2 and 3, for an incident light (30) incident at an incident angle (θ1) of less than about 10 degrees, or less than about 8 degrees, or less than about 6 degrees, or less than about 4 degrees, or less than about 3 degrees, or less than about 2 degrees, or less than about 1 degree, the second optical film (40) may be configured to transmit (T2b, T2g, T2r) greater than about 50% of the incident light for each of the blue (12b), green (12g) and red (12r) peak wavelengths. In some cases, more than 55%, or more than 60%, or more than 65%, or more than 70%, or more than 75%, or more than 80%, and, in some instances, greater than 85% of the incident light (30) incident at an incident angle (θ1) of 0-10 degrees for each of the blue (12b), green (12g) and red (12r) peak wavelengths may be transmitted by the second optical film (40).

In some embodiments, the second optical film (40) may be configured to substantially reflect incident light for a UV wavelength range (50) having only wavelengths less than the blue peak wavelength and may be at least 10 nm, or 15 nm, or 20 nm, or 25 nm, or 30 nm, or 35 nm, or 40 nm wide.

In some examples, the second optical film (40) may include an average optical reflectance of greater than 60% of incident light (30) incident at an incident angle (θ1) of less than about 10 degrees, or less than about 8 degrees, or less than about 6 degrees, or less than about 4 degrees, or less than about 3 degrees, or less than about 2 degrees, or less than about 1 degree for the UV wavelength range (50). In some instances, more than 65%, or more than 70%, or more than 80%, or more than 85%, or more than 90%, or more than 95% of the incident light (30) incident at an incident angle (θ1) of 0-10 degrees for the uv wavelength range may be reflected by the second optical film (40).

In other aspects, the second optical film (40) may be configured to substantially transmit incident light (30) incident at an incident angle (θ2) of greater than about 40 degrees. In some examples, the second optical film (40) may transmit greater than about 50% or greater than about 55%, or greater than about 60%, or greater than about 65%, or greater than about 70%, or greater than about 75%, or greater than about 80%, or greater than about 85%, or greater than about 90%, or greater than about 95% or greater than about 98% of the incident light at an incident angle (θ2) of greater than about 40 degrees, or greater than about 45 degrees, or 50 degrees, or 55 degrees for each of the blue, green and red peak wavelengths.

In other examples, the second optical film (40) may include a high transmittance for the UV wavelength range (50) at oblique incidence. For example, as shown in FIG. 2, the second optical film (40) may include an average optical transmittance of greater than about or 60%, or greater than about 65%, or greater than about 70%, or greater than about 75%, or greater than about 80%, or greater than about 85%, or greater than about 90%, or greater than about 95%, or greater than about 95% of the incident light at an incident angle (θ2) of greater than about 40 degrees, or greater than about 45 degrees, or 50 degrees, or 55 degrees for the UV wavelength range (50).

In some aspects, as illustrated in FIG. 1, one or more barrier layers (110) may be disposed on the one or more light converting layers (10a, 10b). The barrier layer (110) may have low oxygen permeability and/or water vapor permeability. The barrier layer (110) substantially supports and protects the one or more light converting layers (10a, 10b) by substantially blocking moisture or gas from permeating into the light converting layers (10a, 10b). In some instances, the one or more light converting layers (10a, 10b) may be disposed between two barrier layers.

The barrier layer (110) may have sufficient thickness and may be composed of inorganic materials or polymers that transmit light and have a high blocking property with respect to moisture and/or oxygen. For example, the barrier layer (110) may be composed of one or more of SiCN or SiO2 or SiOx, acrylate based polymers or copolymers, or, polyethylene, polypropylene, polyvinyl chloride, polyvinyl alcohol, ethylene vinylalcohol, polychlorotriplefluoroethylene, polyvinylidene chloride, nylon, polyamino ether, and cycloolefin-based homopolymer or copolymer.

In some aspects an optical diffuser (90) may be disposed between the display panel (70) and the light emitting sources (80). In some aspects, as illustrated in FIG. 1, the diffuser film (90) may be disposed between the optical stack (100) and the light emitting sources (80).

The optical diffuser (90) may include surface diffusers, bulk diffusers, and/or embedded diffusers. The diffuser according to some embodiments in this disclosure, may be a separate layer or coating having diffusive properties with respect to visible light or a surface treatment on a layer of the optical construction of the present disclosure that provides diffusive properties to the treated surface (e.g., a surface diffuser). For example, the diffusive element may be a separate layer (e.g., a bulk diffuser) that diffuses visible light and that is either coextruded, coated, or laminated to another layer of the optical construction of the present disclosure. The optical diffuser (90) can further facilitate spreading and recycling of light. In some cases, the optical diffuser (90) may consist of embedded particles that scatter light or may utilize surface structure or both to further improve spatial uniformity and condition the angle distribution for the upper films to maximize efficiency.

The optical diffuser (90) may have a total optical transmittance of greater than about 50%, or greater than about 55%, or greater than about 60%, or greater than about 65%, or greater than about 70%, or greater than about 75%, or greater than about 80% for each of the blue (12b), green (12g) and red (12r) peak wavelengths. For at least the blue peak wavelength (12b), the optical diffuser (90) may have a greater diffuse optical transmittance Td and a smaller specular optical transmittance Ts. In some cases, Td>Ts by at least 10%, or 20%, or 30%. In other cases, the optical diffuser (90) may have a greater diffuse optical transmittance Tdl and a smaller specular optical transmittance Ts1 for each of the blue (12b), green (12g) and red (12r) peak wavelength. In some cases, Td1>Ts1 by at least 10%, or 20%, or 30%.

The optical diffuser (90) may have an average total optical transmittance of greater than about 60%, or greater than about 65%, or greater than about 70%, or greater than about 80% for the UV wavelength range (50). In some cases, for the UV wavelength range (50), the optical diffuser (90) may have a greater total optical reflectance and a smaller total optical transmittance. In some cases, the total optical reflectance of the optical diffuser (90) for the UV wavelength range (50) may be greater than the total optical transmittance by at least 10%, or 20%, or 30%.

One or more brightness enhancement films, for example, prismatic films (120, 130), may be disposed between the display panel (70) and the optical stack (100). A first prismatic film (120) may be disposed between the display panel (70) and the light conversion layers (10a, 10b) and a second prismatic film (130) may be disposed between the display panel (70) and the first prismatic film (120). The prismatic films (120, 130) are usually optically transparent. The prismatic films (120, 130) may be configured to transmit light in an angle distribution to enhance axial illumination, while recycling a portion to improve uniformity and brightness. The prismatic films (120, 130) can also split the incident images to further enhance uniformity. Exemplary prismatic films useful for increasing the brightness of the display panel are offered by 3M Company as Vikuiti™ Brightness Enhancement Films (BEF).

In some aspects, the first prismatic film (120) may include a plurality of first prisms (121) extending along substantially a same first longitudinal direction (y-axis). The second prismatic film (130) may include a plurality of second prisms (131) extending along substantially a same second longitudinal direction (x-axis) different from the first longitudinal direction (y-axis).

In some embodiments, a reflective polarizer (140) may be disposed between the display panel (70) and the optical stack (100). The reflective polarizer (140) may transmit a polarization state parallel to the transmission axis of bottom polarizer of the display panel (70), recycling the orthogonal polarization to enhance brightness and uniformity.

The reflective polarizer (140) may also be configured as a multilayer optical film including a plurality of third layers (21, 22), as shown in FIG. 3, similar to the first and/or second optical films (20, 40). The plurality of third layers (21, 22) may include a plurality of polymeric layers. The plurality of third layers (21, 22) may reflect or transmit light primarily by constructive or destructive optical interference. For instance, the plurality of third layers (21, 22) may have different refractive index characteristics so that some light is reflected at interfaces between adjacent layers. The plurality of third layers (21, 22) may be sufficiently thin so that light reflected at a plurality of interfaces undergoes constructive or destructive interference to give the reflective polarizer (140) the desired reflective or transmissive properties.

The number of the plurality of third layers (21, 22) may be at least 10, or at least 20, or at least 30, or at least 50, or at least 75, or at least 100, or at least 150, or at least 200, or at least 250, or at least 300, or at least 350, or at least 400 in total. Each of the third layers (21, 22) may have an average thickness of less than about 500 nm. In some instances, the average thickness may be less than about 400 nm, or less than about 350 nm, or less than about 300 nm, or less than about 250 nm, or less than about 200 nm. In some aspects, the reflective polarizer (140) may further include at least one skin layer (23) having an average thickness of greater than about 500 nm, or greater than about 750 nm, or greater than about 1000 nm, or greater than about 1500 nm, or greater than about 2000 nm.

In some aspects, for a substantially normally incident light (30) and for each of the blue (12b), green (12g) and red (12r) peak wavelengths, the reflective polarizer (140) including the plurality of third polymer layers (21, 22) may reflect more than 60% of the incident light having an in-plane first polarization state (x-axis). In some embodiments, for a substantially normally incident light (30) and for each of the blue (12b), green (12g) and red (12r) peak wavelengths, the reflective polarizer (140) including the plurality of third polymer layers (21, 22) may reflect more than about 70%, or at least 80%, or at least 90%, or at least 95% of the incident light having an in-plane first polarization state (x-axis).

For a substantially normally incident light (30) and for each of the blue (12b), green (12g) and red (12r) peak wavelengths, the reflective polarizer (140) including the plurality of third polymer layers (21, 22) may transmit more than about 60% of the incident light having an orthogonal in-plane second polarization state (y-axis). In some embodiments, for a substantially normally incident light (30) and for each of the blue (12b), green (12g) and red (12r) peak wavelengths, the reflective polarizer (140) including the plurality of third polymer layers (21, 22) may transmit at least 70%, or at least 80%, or at least 90%, or at least 95% of the incident light having an orthogonal in-plane second polarization state (y-axis).

Descriptions for elements in figures should be understood to apply equally to corresponding elements in other figures, unless indicated otherwise. Although specific embodiments have been illustrated and described herein, it will be appreciated by those of ordinary skill in the art that a variety of alternate and/or equivalent implementations can be substituted for the specific embodiments shown and described without departing from the scope of the present disclosure. This application is intended to cover any adaptations, or variations, or combinations of the specific embodiments discussed herein. Therefore, it is intended that this disclosure be limited only by the claims and the equivalents thereof.

1. An optical stack comprising:
one or more light converting layers comprising a green emission spectrum comprising at least one green peak at a corresponding green peak wavelength and a red emission spectrum comprising at least one red peak at a corresponding red peak wavelength, the one or more light converting layers configured to receive a blue light comprising a blue wavelength spectrum comprising at least one blue peak at a corresponding blue peak wavelength and convert portions of the received blue light to green and red lights within the respective green and red emission spectra; and
a first optical film disposed on, and substantially co-extensive in length and width with, the one or more light converting layers, the first optical film comprising a plurality of first layers numbering at least 4 in total, each of the first layers having an average thickness of less than about 500 nm, such that:
for an incident light incident at an incident angle of less than about 10 degrees, the first optical film transmits greater than about 50% of the incident light for the blue wavelength and reflects greater than about 60% of the incident light for each of the green and red peak wavelengths; and
for an incident light incident at an incident angle of greater than about 40 degrees, the first optical film reflects greater than about 50% of the incident light for each of the blue, green and red peak wavelengths.

2. The optical stack of claim 1, wherein the plurality of first layers comprises a plurality of alternating first organic and first inorganic layers, wherein the first organic layers comprise a polymer, and wherein the first inorganic layers comprise one or more of an oxide, a nitride, a carbide, and a metal.

3. The optical stack of claim 1 further comprising a second optical film disposed on, and substantially co-extensive in length and width with, the one or more light converting layers and the first optical film, the second optical film comprising a plurality of second layers numbering at least 4 in total, each of the second layers having an average thickness of less than about 500 nm, such that for an ultraviolet (uv) wavelength range that includes only wavelengths less than the blue peak wavelength and is at least 10 nm wide:
for an incident light incident at an incident angle of less than about 10 degrees, the second optical film transmits greater than about 50% of the incident light for each of the blue, green and red peak wavelengths, and an average optical reflectance of greater than about 60% for the uv wavelength range; and
for an incident light incident at an incident angle of greater than about 40 degrees, the second optical film transmits greater than about 50% of the incident light for each of the blue, green and red peak wavelengths, and an average optical transmittance of greater than about 60% for the uv wavelength range.

4. A display system comprising a display panel disposed on the optical stack of claim 3 and configured to form an image.

5. The display system of claim 4 further comprising a plurality of discrete spaced apart light sources configured to emit a blue light comprising the blue wavelength spectrum, and wherein at least one of the light sources in the plurality of light sources is further configured to emit a uv light having a uv wavelength in the uv wavelength range.

6. The display system of claim 5 further comprising an optical diffuser disposed between the optical stack and the light sources, the optical diffuser having a total optical transmittance of greater than about 50% for each of the blue, green and red peak wavelengths, and an average total optical transmittance of greater than about 60% for the uv wavelength range.

7. The display system of claim 5, wherein for at least the blue peak wavelength, the optical diffuser has a greater diffuse optical transmittance and a smaller specular optical transmittance, and wherein for the uv wavelength range, the optical diffuser has a greater total optical reflectance and a smaller total optical transmittance.

8. The display system of claim 4 further comprising a reflective polarizer disposed between the display panel and the optical stack and comprising a plurality of third polymeric layers numbering at least 10 in total, each of the third polymeric layers having an average thickness of less than about 500 nm, such that for a substantially normally incident light and each of the blue, green and red peak wavelengths, the plurality of third polymeric layers reflects more than about 60% of the incident light having an in-plane first polarization state and transmits more than about 60% of the incident light having an in-plane orthogonal second polarization state.

9. The optical stack of claim 1, wherein the one or more light converting layers comprise at least first and second light converting layers comprising the respective green and red emission spectra, the first and second light converting layers configured to receive the blue light and convert portions of the received blue light to the green and red lights within the respective green and red emission spectra.

10. A display system comprising:
at least one light source configured to emit a blue light comprising a blue wavelength spectrum comprising at least one blue peak at a corresponding blue peak wavelength, and emit an ultraviolet (uv) light having a uv wavelength less than the blue peak wavelength;
a display panel disposed to receive light from the at least one light source and form an image;
a first optical film disposed between the display panel and a second optical film; and
one or more light converting layers comprising a green emission spectrum comprising at least one green peak at a corresponding green peak wavelength and a red emission spectrum comprising at least one red peak at a corresponding red peak wavelength, the one or more light converting layers configured to receive the emitted blue light and convert portions of the received blue light to green and red lights within the respective green and red emission spectra, such that:
for an incident light incident at an incident angle of less than about 10 degrees, the first optical film transmits greater than about 50% of the incident light for the blue wavelength and reflects greater than about 60% of the incident light for each of the green and red peak wavelengths, and the second optical film transmits greater than about 50% of the incident light for each of the blue, green and red peak wavelengths, and reflects greater than about 60% of the incident light for the uv wavelength; and
for an incident light incident at an incident angle of greater than about 40 degrees, the first optical film reflects greater than about 50% of the incident light for each of the blue, green and red peak wavelengths, and the second optical film transmits greater than about 50% of the incident light for each of the blue, green and red peak wavelengths, and transmits greater than about 60% of the incident light for the uv wavelength.

11. The display system of claim 10, wherein each of the first and second optical films comprises a plurality of polymeric layers numbering at least 4 in total, each of the polymeric layers having an average thickness of less than about 500 nm.

12. The display system of claim 10, wherein the one or more light converting layers comprise at least first and second light converting layers comprising the respective green and red emission spectra, the first and second light converting layers configured to receive the blue light and convert portions of the received blue light to the green and red lights within the respective green and red emission spectra.
